(19) United States
(12) Patent Application Publication
(10) Pub. No.: US 2025/0070772 A1
(43) Pub. Date: Feb. 27, 2025

(54) DRIVER CIRCUIT

(71) Applicant: Apple Inc., Cupertino, CA (US)

(72) Inventors: Sumit RAO, Cupertino, CA (US); Mitesh D. KATAKWAR, Cupertino, CA (US); Chung-Chi HUANG, Cupertino, CA (US); Craig B. BYINGTON, Cupertino, CA (US)

(73) Assignee: Apple Inc., Cupertino, CA (US)

(21) Appl. No.: 18/455,781

(22) Filed: Aug. 25, 2023

(51) Int. Cl. H03K 17/06; G11C 5/14; H03K 17/687

(52) U.S. Cl. CPC H03K 17/063; G11C 5/147; H03K 17/6872

(57) ABSTRACT

The present disclosure is directed to circuits and a method for mitigating effects of power supply variations on a driver circuit. For example, the circuit can include a first transistor device with a first source/drain (S/D) terminal and a second S/D terminal. The circuit can also include a second transistor device with a third S/D terminal and a fourth S/D terminal. The driver circuit can further include a resistor device electrically connected between the first and third S/D terminals or between the second and fourth S/D terminals. The resistor device can mitigate variations in a high-level output voltage of the driver circuit due to power supply variations.

### FIELD

This disclosure relates to a driver circuit and, more particularly, to driver circuit for a controller device.

### BACKGROUND

In computer systems, controller devices can be used to write data to memory devices to store information for use by the computer or related computer hardware. An example of such memory device is a dynamic random access memory (DRAM) device. DRAM devices can include a capacitive device and one or more transistors to pass a charge to the capacitive device. A charged and discharged capacitive device can represent two values of a bit of data, such as a logic low value (e.g., a digital ‘0’) and a logic high value (e.g., a digital ‘1’). Because the charge on the capacitive device can gradually leak away, DRAM devices require a memory refresh operation to periodically rewrite data into the capacitive device. Controller devices can be used to write and re-write (e.g., for the memory refresh operation) data into the capacitive device.

### SUMMARY

Embodiments of the present disclosure include a driver circuit for mitigating effects of power supply variations. The driver circuit can include a first transistor device with a first source/drain (S/D) terminal and a second S/D terminal. The driver circuit can also include a second transistor device with a third S/D terminal and a fourth S/D terminal. The driver circuit can further include a resistor device electrically connected between the first and third S/D terminals or between the second and fourth S/D terminals. The resistor device can mitigate variations in a high-level output voltage (VOH) of the driver circuit due to power supply variations.

Embodiments of the present disclosure include another driver circuit for mitigating effects of power supply variations. The driver circuit can include a first transistor device with a first S/D terminal and a second S/D terminal. The driver circuit can also include a second transistor device with a third S/D terminal and a fourth S/D terminal, where the third S/D terminal is electrically connected to the first S/D terminal and the fourth S/D terminal is electrically connected to the second S/D terminal. The driver circuit can further include a resistor device electrically connected to the first and third S/D terminals or to the second and fourth S/D terminals. The resistor device can mitigate variations in a VOH of the driver circuit due to power supply variations.

Embodiments of the present disclosure further include a method for mitigating effects of power supply variations in a driver circuit. The method can include activating, with a first reference supply voltage, a first pull-up device to pass a power supply voltage to an external circuit. The method can also include activating, with a second reference supply voltage different from the first reference supply voltage, a second pull-up device to pass the power supply voltage to the external circuit concurrently with the first pull-up device. The method can also include, in response to the first pull-up device being activated or the second pull-up device being activated, flowing a current through a resistor device from a power supply source of the power supply voltage to the external circuit. The resistor device can mitigate variations in a VOH of the driver circuit due to variations in the second reference supply voltage.

### BRIEF DESCRIPTION OF THE DRAWINGS

Aspects of the present disclosure are best understood from the following detailed description when read with the accompanying figures. It is noted that, according to the standard practice in the industry, various features are not drawn to scale. In fact, the dimensions of the various features may be arbitrarily increased or reduced for clarity of discussion.

FIG. 1 is an illustration of a block-level representation of a system, according to some embodiments.

FIG. 2 is an illustration of a block-level representation of a memory device, according to some embodiments.

FIG. 3 is an illustration of a circuit-level representation of a portion of a system, according to some embodiments.

FIG. 4 is an illustration of a first circuit-level representation of a pull-up circuit, according to some embodiments.

FIG. 5 is an illustration of a second circuit-level representation of a pull-up circuit, according to some embodiments.

FIG. 6 is an illustration of a third circuit-level representation of a pull-up circuit, according to some embodiments.

FIG. 7 is an illustration of a fourth circuit-level representation of a pull-up circuit, according to some embodiments.

FIG. 8 is an illustration of a fifth circuit-level representation of a pull-up circuit, according to some embodiments.

FIG. 9 is an illustration of a method for mitigating effects of power supply variations in a driver circuit, according to some embodiments.

FIG. 10 is an illustration of various exemplary systems or devices that can include the disclosed embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. In addition, the present disclosure repeats reference numerals and/or letters in the various examples. This repetition is for the purpose of simplicity and clarity and, unless indicated otherwise, does not in itself dictate a relationship between the various embodiments and/or configurations discussed.

It is noted that references in the specification to “one embodiment,” “an embodiment,” “an example embodiment,” and “exemplary” indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

It is to be understood that the phraseology or terminology herein is for the purpose of description and not of limitation, such that the terminology or phraseology of the present specification is to be interpreted by those skilled in relevant art(s) in light of the teachings herein.

The following disclosure is directed to aspects of a driver circuit, such as a driver circuit for a controller device. In some embodiments, the driver circuit for the controller device can include a first transistor device with a first source/drain (S/D) terminal and a second S/D terminal. The driver circuit can also include a second transistor device with a third S/D terminal and a fourth S/D terminal. The driver circuit can further include a resistor device electrically connected between the first and third S/D terminals or between the second and fourth S/D terminals. Alternatively, the third S/D terminal can be electrically connected to the first S/D terminal, the fourth S/D terminal can be electrically connected to the second S/D terminal, and the resistor device can be electrically connected to the first and third S/D terminals or to the second and fourth S/D terminals. The resistor device can mitigate variations in a high-level output voltage (VOH) of the driver circuit due to power supply variations.

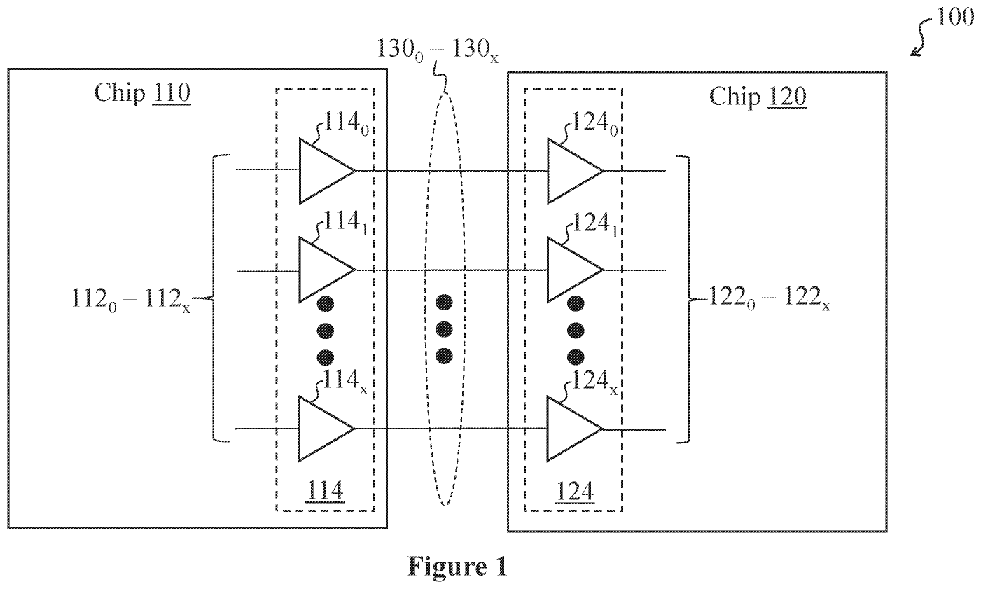

FIG. 1 is an illustration of a block-level representation of a system 100, according to some embodiments. In some embodiments, system 100 can include a chip 110 and a chip 120.

In some embodiments, chip 110 can be a controller device to provide write signals 112₀-112ₓ to a driver circuit 114, where ‘x’ is an integer greater than 2. Driver circuit 114 can include multiple driver circuits 114₀-114ₓ to transfer write signals 112₀-112ₓ to chip 120 via channels 130₀-130ₓ, respectively. In some embodiments, chip 110 can be an integrated circuit or a system on chip (SOC) that includes a processor circuit, a memory interface (e.g., via driver circuit 114), and an input/output (I/O) interface. In some embodiments, the processor circuit can include a general-purpose processor to perform computational operations, such as a central processing unit. The processor circuit can also include other types of processing units, such as a graphics processing unit, an application-specific circuit, and a field-programmable gate array circuit.

In some embodiments, chip 120 can be a memory device, such as a DRAM device. Chip 120 can include a driver circuit 124 to receive signals via channels 130₀-130ₓ. Driver circuit 124 can include multiple driver circuits 124₀-124ₓ to receive write signals 112₀-112ₓ from chip 110 via channels 130₀-130ₓ, respectively, and to output write signals 122₀-122ₓ, respectively, for further processing by chip 120.

In some embodiments, each of channels 130₀-130ₓ can be an interconnect between chip 110 and chip 120 For example, chip 110 and chip 120 can each be an integrated circuit on a printed circuit board, where channels 130₀-130ₓ are disposed on and/or within the printed circuit board as interconnects to transfer electrical signals from chip 110 to chip 120.

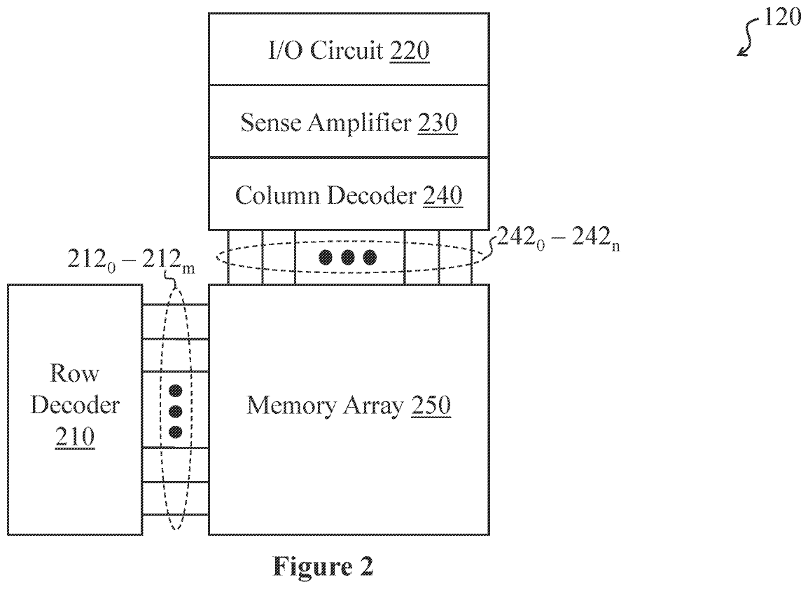

FIG. 2 is an illustration of a block-level representation of chip 120, according to some embodiments. In some embodiments, chip 120 can be a memory device with a row decoder 210, an I/O circuit 220, a sense amplifier 230, a column decoder 240, and a memory array 250.

Memory array 250 includes memory cells arranged in rows and columns that are accessed—e.g., for memory read operations and memory write operations—using a memory address. In some embodiments, the memory cells in memory array 250 can be DRAM cells. Memory array 250 can be arranged as an array of m wordlines (e.g., via wordlines 212₀-212ₘ) and n bitlines (e.g., via bitlines 242₀-242ₙ), where ‘m’ and ‘n’ are integers greater than 2. Though the description below is in the context of DRAM cells, other types of memory cells and other types of circuits can implement the embodiments described herein.

Based on the memory address, row decoder 210 selects a row of memory cells to access (e.g., via wordlines 212₀-212ₘ) and column decoder 140 selects a column of memory cells to access (e.g., via bitlines 242₀-242ₙ). An intersection of the selected row of memory cells and the selected column of memory cells corresponds to a selected memory cell in memory array 250 that can be accessed. For a memory write operation, sense amplifier 230 passes a first voltage (e.g., a power supply voltage, such as 0.6 V, 0.8 V, 1.0 V, 1.2 V, 1.4 V, 1.6 V, 1.8 V, 2.0V, and any other suitable voltage) or a second voltage (e.g., ground, such as 0 V) to the selected memory cell. The first voltage can correspond to a logic high value (e.g., a digital ‘1’) and the second voltage can correspond to a logic low value (e.g., a digital ‘0’), according to some embodiments. In some embodiments, sense amplifier 230 receives the first voltage and the second voltage from I/O circuit 220.

For a DRAM cell with a capacitive device configured to store charge, the capacitive device can either charge to the first voltage or discharge to the second voltage. For a memory read operation, sense amplifier 230 senses a voltage on a selected column (e.g., selected bitline of a DRAM array) to determine whether the selected memory cell is storing a digital ‘0’ or a digital ‘1’. Other memory operations can be performed using row decoder 210, sense amplifier 230, column decoder 240, and memory array 250. These other memory operations are within the spirit and scope of the present disclosure

In some embodiments, with regard to the first voltage and second voltage passed by sense amplifier 230 to the selected memory cell during the memory write operation, I/O circuit 220 can receive these voltages from an external circuit, device, or chip, in which I/O circuit 220 provides the voltages to sense amplifier 230. In some embodiments, referring to FIGS. 1 and 2, I/O) circuit 220 can receive the first voltage and the second voltage from write signals 122₀-122ₓ, which are transmitted by chip 110. Specifically, as discussed above with respect to FIG. 1, driver circuits 124₀-124ₓ receive write signals 112₀-112ₓ from driver circuits 114₀-114ₓ via channels 130₀-130ₓ.

A challenge, among others, in the design of system 100 is ensuring a reliable memory write operation. For example, to write a logic high value (e.g., a digital ‘1’) to the capacitive device in the DRAM cell, variations in a power supply of system 100 can prevent the capacitive device from being fully charged-thus causing data storage errors. For example, referring to FIGS. 1 and 2, driver circuit 1140 of chip 110 can transfer a logic high value (e.g., a digital ‘1’ representing a power supply voltage, such as 0.6 V, 0.8 V, 1.0 V, 1.2 V, 1.4 V, 1.6 V, 1.8 V, 2.0 V, and any other suitable voltage) to driver circuit 124₀ of chip 120 via interconnect 130. Due to an impedance of a pull-up circuit in driver circuit 114₀, an impedance of interconnect 130₀ (e.g., impedance of a metal trace, such as a copper trace, on a printed circuit board), and an impedance at an input of driver circuit 124₀, a voltage drop can occur between chip 110 and chip 120 when transferring the logic high value. This voltage drop can lower an expected voltage level at the input of driver circuit 124₀, resulting in an incorrect output of driver circuit 124₀ as write signal 122₀. The incorrect write signal 122₀ is processed by chip 120 (e.g., a DRAM device)—as described above—resulting in an incorrect memory write operation and a data storage error.

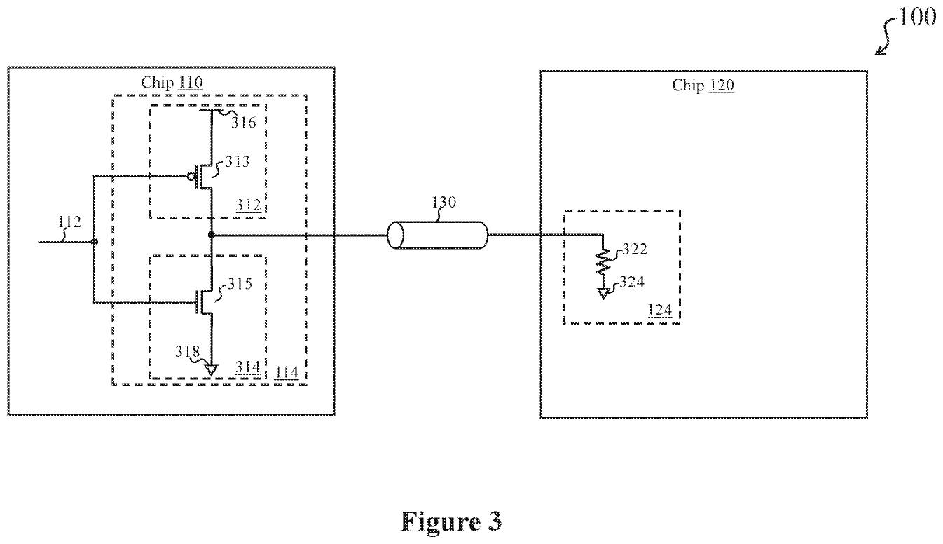

FIG. 3 is an illustration of a circuit-level representation of a portion of system 100—including driver circuit 114, interconnect 130, and driver circuit 124—according to some embodiments. FIG. 3 will be used to facilitate in the description of data storage errors that may occur in system 100 during memory write operations.

For simplicity, a single write signal 112, a single driver circuit 114, a single interconnect 130, and a single driver circuit 124 are shown in FIG. 3. Interconnect 130 is drawn as a cylindrical shape to represent its impedance between driver circuit 114 and driver circuit 124. Driver circuit 124 is drawn as a resistor 322 with one terminal connected to interconnect 130 and another terminal connected to a reference supply voltage 324 (e.g., ground, such as 0 V). Resistor 322 represents an input resistance of driver circuit 124. For example, if driver circuit 124 has an inverter circuit topology with a pull-up circuit having a p-type transistor with a gate terminal electrically connected to a gate terminal of an n-type transistor of a pull-down circuit-in which the gate terminals of the p-type transistor and the n-type transistor are electrically connected to interconnect 130—then resistor 322 can represent the resistance at the gate terminals of the p-type and n-type transistors.

Driver circuit 114 includes a pull-up circuit 312 and a pull-down circuit 314, according to some embodiments. To provide a logic low value (e.g., ground, such as 0 V) to driver circuit 124, pull-down circuit 314 can be enabled by write signal 112 to “pull down” interconnect 130 to a voltage level of reference supply voltage 318 (e.g., ground, such as 0 V). In some embodiments, pull-down circuit 314 can include an n-type transistor 315 with a gate terminal electrically connected to write signal 112, a first S/D terminal electrically connected to interconnect 130, and a second S/D terminal electrically connected to reference supply voltage 318--thus, when write signal 112 is at a logic high value (e.g., a digital ‘1’ representing a power supply voltage, such as 0.6 V, 0.8 V, 1.0 V, 1.2 V, 1.4 V, 1.6 V, 1.8 V, 2.0 V, and any other suitable voltage), an electrical path is created between interconnect 130 and reference supply voltage 318.

To provide a logic high value (e.g., a power supply voltage, such as 0.6 V, 0.8 V, 1.0V, 1.2 V, 1.4 V, 1.6 V, 1.8 V, 2.0 V, and any other suitable voltage) to driver circuit 124, pull-up circuit 312 can be enabled by write signal 112 to “pull up” interconnect 130 to a voltage level of a reference supply voltage 316 (e.g., a power supply voltage, such as 0.6 V, 0.8 V, 1.0 V, 1.2 V, 1.4 V, 1.6 V, 1.8 V, 2.0 V, and any other suitable voltage). In some embodiments, pull-up circuit 312 can include a p-type transistor 313 with a gate terminal electrically connected to write signal 112, a first S/D terminal electrically connected to interconnect 130, and a second S/D terminal electrically connected to reference voltage supply 316—thus, when write signal 112 is at a logic low value (e.g., ground, such as 0 V), an electrical path is created between interconnect 130 and reference voltage supply 316.

A challenge in the design of pull-up circuit 312 can be the voltage level of write signal 112 to “turn on” (or activate) p-type transistor 313. For example, the voltage level of write signal 112 can be based on a power supply (e.g., reference voltage supply 316), which can have a voltage range (e.g., between 0.4 V and 0.6 V). The current drive of p-type transistor 313 can depend on the voltage level of the power supply and, if the voltage level of the power supply is not sufficiently low, a resistance path between driver circuit 114 and driver circuit 124 (e.g., about 30 Ω to about 40 Ω) can increase. An increase in the resistance path can result in a data storage error in chip 120 during the memory write operation because a lower than expected voltage level at the input of driver circuit 124 can occur. Embodiments of the present disclosure are directed to driver circuits—in particular, pull—up circuits-that mitigate variations in its VOH due to power supply variations

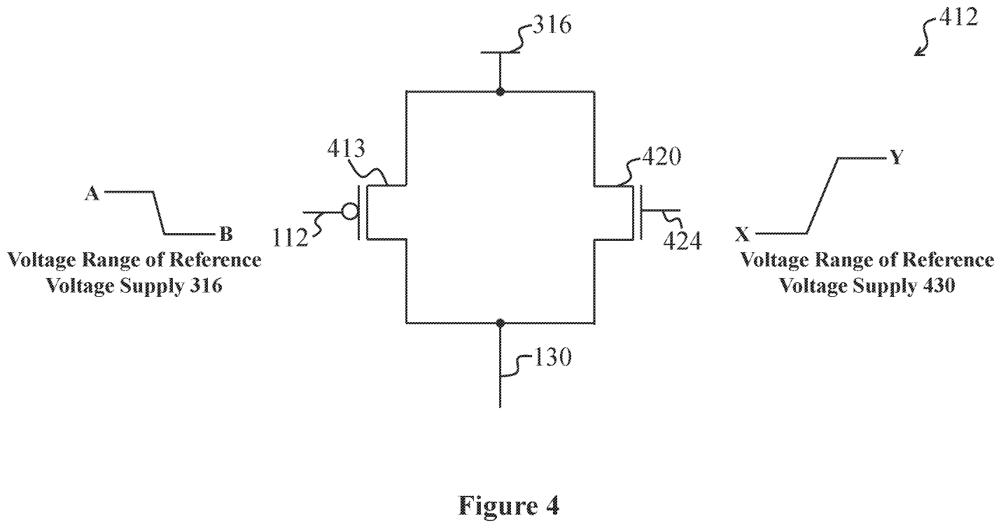

FIG. 4 is an illustration of a first embodiment of a circuit-level representation of a pull-up circuit 412, according to some embodiments Pull-up circuit 412 can replace pull-up circuit 312 in FIG. 3, according to some embodiments. Pull-up circuit 412 includes a pull-up transistor 413 and a pull-up assist transistor 420.

Pull-up transistor 413 can be a p-type transistor, such as a p-type metal-oxide semiconductor field-effect transistor (MOSFET), a p-type fin field-effect transistor (FinFET), a p-type gate-all-around field-effect transistor (GAAFET), a p-type gallium nitride field effect transistor (GaNFET), or any other suitable type of transistor. A gate terminal of pull-up transistor 413 can receive write signal 112 based on a voltage range of reference voltage supply 316 In some embodiments, a lower end of the voltage range of reference voltage supply 316 (e.g., voltage ‘B’ in FIG. 4) can be above 0 V, such as 0.4 V, and the upper end of the voltage range of reference voltage supply 316 (e.g., voltage ‘A’ in FIG. 4) can be at about 0.6 V or any other suitable upper end voltage value. Because the current drive of pull-up transistor 413 is based on the voltage range of reference voltage supply 316 (e.g., a range between voltage ‘A’ and voltage ‘B’), a resistance path between driver circuit 114 and driver circuit 124 is also based on the voltage range of reference voltage supply 316—e.g., a higher voltage for reference voltage supply 316 results in an increase in the resistance path. Put differently, though the lower end of the voltage range of reference voltage supply 226 may be, for example, 0.4 V, this voltage may not be sufficiently low to lower the resistance path between driver circuit 114 and driver circuit 124 to a target resistance path value (e.g., about 30 Ω to about 40 Ω).

To further lower the resistance path between driver circuit 114 and driver circuit 124, pull-up assist transistor 420 can be placed in a parallel arrangement with pull-up transistor 413 as shown in FIG. 4, according to some embodiments. Pull-up assist transistor 420 can be an n-type transistor, such as an n-type MOSFET, an n-type FinFET, an n-type GAAFET, an n-type GaNFET, or any other suitable type of transistor. As shown in FIG. 4, pull-up transistor 413 and pull-up assist transistor 420 share a first common S/D terminal electrically connected to reference voltage supply 316 and a second common S/D terminal electrically connected to interconnect 130. In some embodiments, a gate terminal of pull-up assist transistor 420 can receive a pull-up enable signal 424 based on a voltage range of a reference voltage supply 430 (e.g., a power supply voltage) different from reference voltage supply 316. Reference voltage supply 430 can have a different voltage range (e.g, between about 0.5 V and about 1.2 V) than that of reference voltage supply 316 (e.g., between about 0.4 V and about 0.6 V), according to some embodiments.

In some embodiments, reference voltage supply 430 can be a frequency-scalable power supply voltage. For example, at a lower frequency operation of system 100 (e.g., about 800 MHZ), reference voltage supply 430 can be at a lower end of its voltage range (e.g., 0.5 V). And, at a higher frequency operation of system 100 (e.g., about 1 GHz), reference voltage supply voltage 430 can be at an upper end of its voltage range (e.g., about 1.2 V). In FIG. 4, the voltage range of reference voltage supply 430 is represented by voltage ‘X’ at a lower end of the voltage range (e.g., about 0.5 V) and voltage ‘Y’ at an upper end of the voltage range (e.g., about 1.2 V).

Referring to FIGS. 3 and 4, during a memory write operation and in response to write signal 112 and pull-up enable signal 424 concurrently turning on (or activating) pull-up transistor 413 (e.g., with a voltage at the lower end of the voltage range of reference voltage supply 316) and pull-up assist transistor 420 (e.g., with a voltage at the upper end of the voltage range of reference voltage supply 430) to provide a logic high value (e.g., a digital ‘1’) to driver circuit 124, an insufficient current drive by pull-up transistor 410 can be mitigated by pull-up assist transistor 420. Put differently, in addition to pull-up transistor 413 providing a current path between reference voltage supply 316 and interconnect 130, pull-up assist transistor 420 provides another current path between reference voltage supply 316 and interconnect 130, thus lowering an overall resistance path between driver circuit 114 and driver circuit 124 and ensuring a reliable memory write operation.

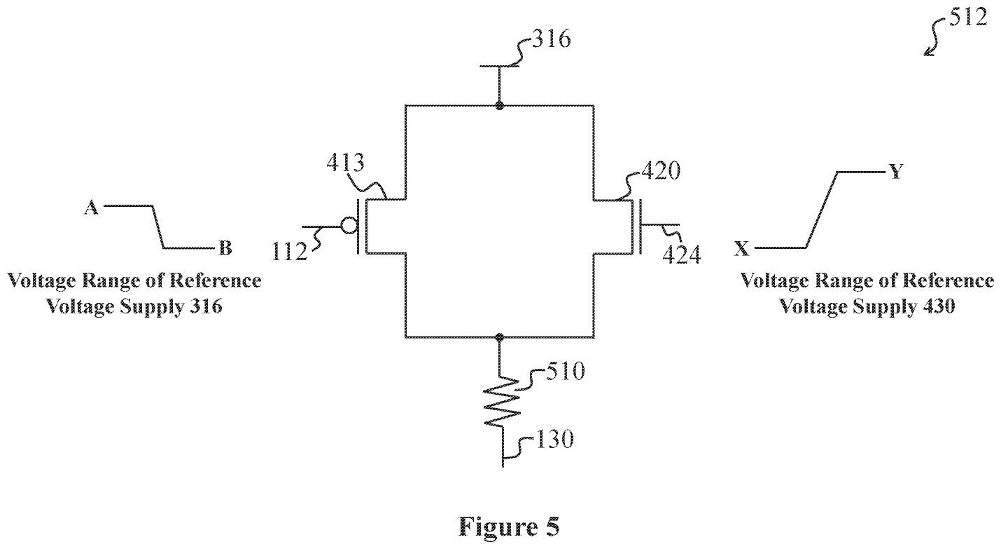

FIG. 5 is an illustration of a second embodiment of a circuit-level representation of a pull-up circuit 512, according to some embodiments. Pull-up circuit 512 can replace pull-up circuit 312 in FIG. 3, according to some embodiments. Pull-up circuit 512 includes pull-up transistor 413, pull-up assist transistor 420, and a resistor device 510. Pull-up transistor 413 and pull-up assist transistor 420 are described above, with respect to FIG. 4.

In some embodiments, resistor device 510 can be a passive resistor integrated in the same package or the same substrate as pull-up transistor 413 and pull-up assist transistor 420. At a first terminal, resistor device 510 can be electrically connected to a S/D terminal shared by pull-up transistor 413 and pull-up assist transistor 420, as shown in FIG. 5. And, at a second terminal, resistor device 510 can be electrically connected to interconnect 130, as shown in FIG. 5. In some embodiments, resistor device 510 can be sized to be about 1.5 times to about 4 times larger than pull-up assist transistor 420

In some embodiments, resistor device 510 mitigates an impact of voltage fluctuations in reference voltage supply 430, which pull-up enable signal 424 applies at the gate terminal of pull-up assist transistor 420. For example, due to “noisy” circuits in system 100 (e.g., circuits with high-speed switching) that receive reference voltage supply 330, the voltage of reference voltage supply 330 can vary and the current drive of pull-up assist transistor 420 can fluctuate accordingly. As a result, the resistance path between driver circuit 114 and driver circuit 124 can vary by, for example, about 30% and the VOH of driver circuit 114 can vary by, for example, about 200 m V. Resistor device 510 can mitigate these variances by reducing a resistance dependence on pull-up assist transistor 420 and allocating a portion of the resistance in the resistance path—e.g., between reference voltage supply 316 and interconnect 130 and through pull-up assist transistor 420—to resistor device 510, according to some embodiments. In some embodiments, resistor device 510 can contribute about 70% of the total resistance in the resistance path (e.g., between reference voltage supply 316 and interconnect 130 and through pull-up assist transistor 420). For example, if the total resistance in the resistance path is about 715 Ω, then the resistance contribution from resistor device 510 is about 500 Ω and the resistance contribution from pull-up assist transistor 420 is about 215 Ω.

Referring to FIGS. 3 and 5, for a target resistance path between driver circuit 114 and driver circuit 124 (e.g., about 30 Ω to about 40 Ω), pull-up transistor 413 can be re-sized and resistor device 510 can be electrically between a common S/D terminal of pull-up transistor 413 and pull-up assist transistor 420 and interconnect 130, according to some embodiments. For example, to minimize the variation in the VOH of driver circuit 114, pull-up transistor 413 can be re-sized to be about 3 times to about 4 times larger than its original design (e.g., from FIG. 4) and resistor device 510 can be electrically connected between the common S/D terminal of pull-up transistor 413 and pull-up assist transistor 420 and interconnect 130. The re-sizing of pull-up transistor 413 indicates that a significant amount of current flows through pull-up transistor 413—due to fluctuations that cause a low voltage in reference voltage supply 430 (e.g., about 0.5 V to 0.7 V)—to achieve the target resistance path. In some embodiments, with the re-sizing of pull-up transistor 413 and the placement of resistor device 510 as shown in FIG. 5, the variance in the VOH of driver circuit 114 can be reduced by about 10 times (e.g., from about 200 mV to about 20 mV).

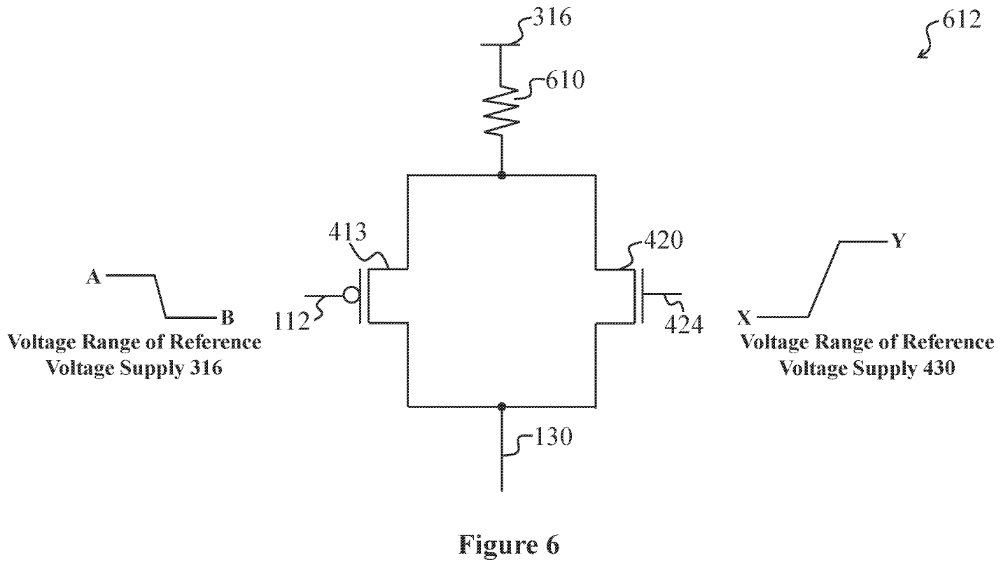

FIG. 6 is an illustration of a third embodiment of a circuit-level representation of a pull-up circuit 612, according to some embodiments. Pull-up circuit 612 can replace pull-up circuit 312 in FIG. 3, according to some embodiments. Pull-up circuit 612 includes pull-up transistor 413, pull-up assist transistor 420, and a resistor device 610. Pull-up transistor 413 and pull-up assist transistor 420 are described above, with respect to FIG. 4

In some embodiments, resistor device 610 can be a passive resistor integrated in the same package or the same substrate as pull-up transistor 413 and pull-up assist transistor 420. At a first terminal, resistor device 610 can be electrically connected to a S/D terminal shared by pull-up transistor 413 and pull-up assist transistor 420, as shown in FIG. 6. And, at a second terminal, resistor device 610 can be electrically connected to reference voltage supply 316, as shown in FIG. 6. In some embodiments, resistor device 610 can be sized to be about 1.5 times to about 4 times larger than pull-up assist transistor 420.

Similar to resistor device 510 of FIG. 5, resistor device 610 mitigates an impact of voltage fluctuations in reference voltage supply 430, which pull-up enable signal 424 applies at the gate terminal of pull-up assist transistor 420, according to some embodiments. Resistor device 610 can mitigate these variances by reducing a resistance dependence on pull-up assist transistor 420 and allocating a portion of the resistance in the resistance path—e.g., between reference voltage supply 316 and interconnect 130 and through pull-up assist transistor 420—to resistor device 610, according to some embodiments. In some embodiments, resistor device 610 can contribute about 70% of the total resistance in the resistance path (e.g., between reference voltage supply 316 and interconnect 130 and through pull-up assist transistor 420).

Referring to FIGS. 3 and 6, for a target resistance path between driver circuit 114 and driver circuit 124 (e.g., about 30 Ω to about 40 Ω), pull-up transistor 413 can be re-sized and resistor device 610 can be electrically connected between a common S/D terminal of pull-up transistor 413 and pull-up assist transistor 420 and reference voltage supply 316, according to some embodiments. For example, to minimize the variation in the VOH of driver circuit 114, pull-up transistor 413 can be re-sized to be about 2.5 times to about 3.5 times larger than its original design (e.g., from FIG. 4) and resistor device 610 can be electrically connected between the common S/D terminal of pull-up transistor 413 and pull-up assist transistor 420 and reference voltage supply 316. The re-sizing of pull-up transistor 413 indicates that a significant amount of current flows through pull-up transistor 413—due to fluctuations that cause a low voltage in reference voltage supply 430 (e.g., about 0.5 V to 0.7 V)—to achieve the target resistance path. In some embodiments, with the re-sizing of pull-up transistor 413 and the placement of resistor device 610 as shown in FIG. 6, the variance in the VOH of driver circuit 114 can be reduced by about 5 times (e.g., from about 200 mV to about 40 mV).

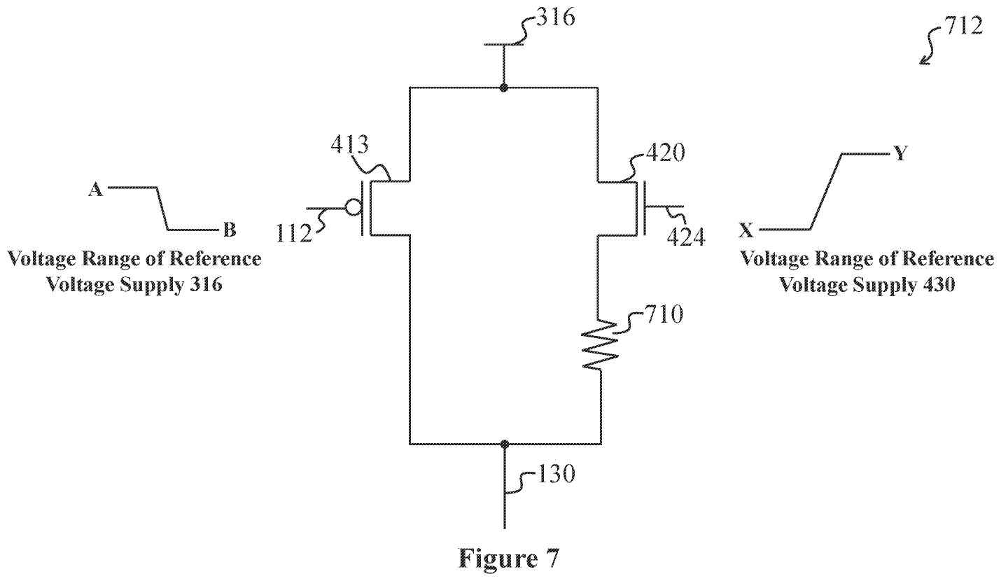

FIG. 7 is an illustration of a fourth embodiment of a circuit-level representation of a pull-up circuit 712, according to some embodiments. Pull-up circuit 712 can replace pull-up circuit 312 in FIG. 3, according to some embodiments. Pull-up circuit 712 includes pull-up transistor 413, pull-up assist transistor 420, and a resistor device 710. Pull-up transistor 413 and pull-up assist transistor 420 are described above, with respect to FIG. 4.

In some embodiments, resistor device 710 can be a passive resistor integrated in the same package or the same substrate as pull-up transistor 413 and pull-up assist transistor 420. At a first terminal, resistor device 710 can be electrically connected to a S/D terminal of pull-up assist transistor 420, as shown in FIG. 7. And, at a second terminal, resistor device 710 can be electrically connected to a S/D terminal of pull-up transistor 413 and interconnect 130, as shown in FIG. 7. In some embodiments, resistor device 710 can be sized to be about 1.5 times to about 4 times larger than pull-up assist transistor 420.

Similar to resistor device 510 of Figure S and resistor device 610 of FIG. 6, resistor device 710 mitigates an impact of voltage fluctuations in reference voltage supply 430, which pull-up enable signal 424 applies at the gate terminal of pull-up assist transistor 420, according to some embodiments. Resistor device 710 can mitigate these variances by reducing a resistance dependence on pull-up assist transistor 420 and allocating a portion of the resistance in the resistance path—e.g., between reference voltage supply 316 and interconnect 130 and through pull-up assist transistor 420—to resistor device 710, according to some embodiments. In some embodiments, resistor device 710 can contribute about 70% of the total resistance in the resistance path (e.g., between reference voltage supply 316 and interconnect 130 and through pull-up assist transistor 420).

Referring to FIGS. 3 and 7, for a target resistance path between driver circuit 114 and driver circuit 124 (e.g, about 30 Ω to about 40 Ω), pull-up assist transistor 420 can be re-sized and resistor device 710 can be electrically connected between a S/D terminal of pull-up assist transistor 420 and a S/D terminal of pull-up transistor 413 (and between the S/D terminal of pull-up assist transistor 420 and interconnect 130), according to some embodiments. For example, to minimize the variation in the VOH of driver circuit 114, pull-up assist transistor 420 can be re-sized to be about 2 times to about 3 times larger than its original design (e.g., from FIG. 4) and resistor device 710 can be electrically connected between the S/D terminal of pull-up assist transistor 420 and the S/D terminal of pull-up transistor 413 (and between the S/D terminal of pull-up assist transistor 420 and interconnect 130). The re-sizing of pull-up assist transistor 420 indicates that a significant amount of current flows through pull-up assist transistor 420—due to fluctuations that cause a low voltage in reference voltage supply 430 (e.g., about 0.5 V to 0.7 V)—to achieve the target resistance path. In some embodiments, with the re-sizing of pull-up assist transistor 420 and the placement of resistor device 710 as shown in FIG. 7, the variance in the VOH of driver circuit 114 can be reduced by about 13 times (e.g., from about 200mV to about 15 mV).

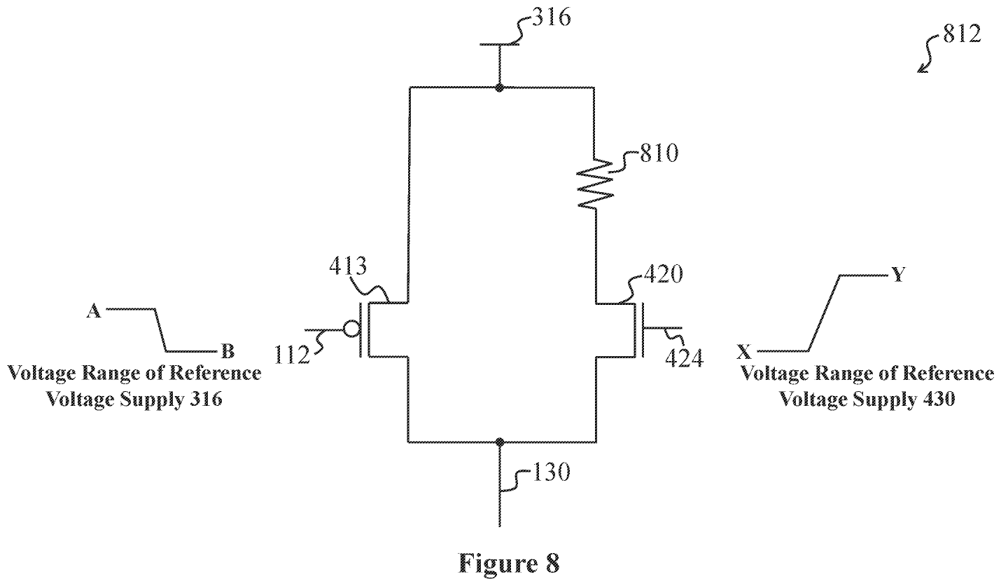

FIG. 8 is an illustration of a fifth embodiment of a circuit-level representation of a pull-up circuit 812, according to some embodiments. Pull-up circuit 812 can replace pull-up circuit 312 in FIG. 3 according to some embodiments. Pull-up circuit 812 includes pull-up transistor 413, pull-up assist transistor 420, and a resistor device 810. Pull-up transistor 413 and pull-up assist transistor 420 are described above, with respect to FIG. 4.

In some embodiments, resistor device 810 can be a passive resistor integrated in the same package or the same substrate as pull-up transistor 413 and pull-up assist transistor 420. At a first terminal, resistor device 810 can be electrically connected to reference voltage supply 316 and a S/D terminal of pull-up transistor 413, as shown in FIG. 8. And, at a second terminal, resistor device 810 can be electrically connected to a S/D terminal of pull-up assist transistor 420, as shown in FIG. 8. In some embodiments, resistor device 810 can be sized to be about 1 5 times to about 4 times larger than pull-up assist transistor 420.

Similar to resistor device 510 of FIG. 5, resistor device 610 of FIG. 6, and resistor device 710 of FIG. 7, resistor device 810 mitigates an impact of voltage fluctuations in reference voltage supply 430, which pull-up enable signal 424 applies at the gate terminal of pull-up assist transistor 420, according to some embodiments. Resistor device 810 can mitigate these variances by reducing a resistance dependence on pull-up assist transistor 420 and allocating a portion of the resistance in the resistance path—e.g., between reference voltage supply 316 and interconnect 130 and through pull-up assist transistor 420—to resistor device 810, according to some embodiments. In some embodiments, resistor device 810 can contribute about 70% of the total resistance in the resistance path (e.g., between reference voltage supply 316 and interconnect 130 and through pull-up assist transistor 420).

Referring to FIGS. 3 and 8, for a target resistance path between driver circuit 114 and driver circuit 124 (e.g., about 30 Ω to about 40 Ω), pull-up transistor 413 and pull-up assist transistor 420 can remain substantially the same size as their original design (e.g., from FIG. 4) and resistor device 810 can be electrically connected between reference voltage supply 316 and a S/D terminal of pull-up assist transistor 420 (and between a S/D terminal of pull-up transistor 413 and the S/D terminal of pull-up assist transistor 420), according to some embodiments. In some embodiments, with the placement of resistor device 810 as shown in FIG. 8, the variance in the VOH of driver circuit 114 can be reduced by about 20 times (e.g., from about 200 m V to about 10 mV).

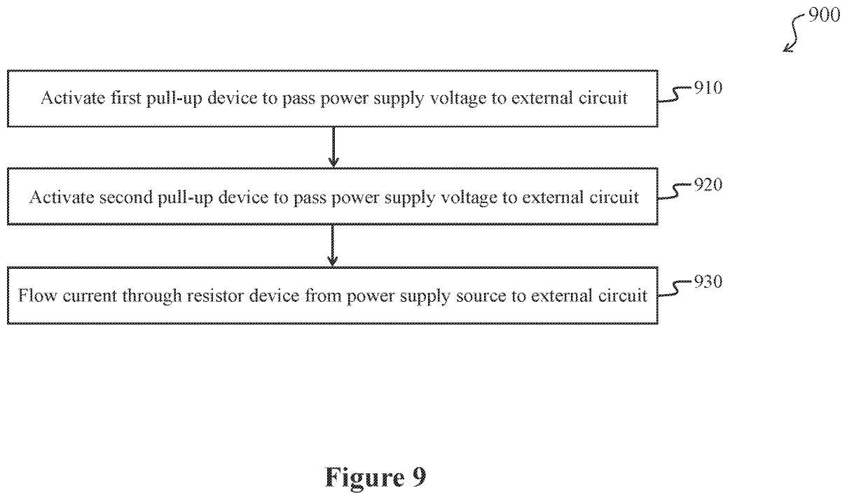

FIG. 9 is an illustration of a method 900 for mitigating effects of power supply variations in a driver circuit, according to some embodiments. For illustrative purposes, the operations illustrated in method 900 will be described with reference to the system and associated circuits described above with respect to FIGS. 3 and 5-8. Other representations of the system and associated circuits are within the scope of the present disclosure. Also, additional operations may be performed between various operations of method 900 and may be omitted merely for clarity and ease of description. The additional operations can be provided before, during, and/or after method 900, in which one or more of these additional operations are briefly described herein. Moreover, not all operations may be needed to perform the disclosure provided herein Additionally, some of the operations may be performed simultaneously or in a different order than shown in FIG. 9. In some embodiments, one or more other operations may be performed in addition to or in place of the presently-described operations.

Referring to FIG. 9, at operation 910, a first pull-up device is activated with a first reference supply voltage to pass a power supply voltage to an interconnect. Referring to FIGS. 3 and 5-8, pull-up transistor 413 (e.g., a first pull-up device) is activated by write signal 112 based on a voltage range of reference voltage supply 316 (e.g., a first reference supply voltage) to pass a power supply voltage to an external circuit (e.g, driver circuit 124 of chip 120) via interconnect 130. Pull-up transistor 413 passes a power supply voltage from reference voltage supply 316 to interconnect 130, which is electrically connected to driver circuit 124. In some embodiments, pull-up transistor 310 can be a p-type transistor.

Referring to FIG. 9, at operation 920, a second pull-up device is activated with a second reference supply voltage to pass the power supply voltage to the external circuit concurrently with the first pull-up device. In some embodiments, the second reference supply voltage is different from the first reference supply voltage. Referring to FIGS. 3 and 5-8, pull-up assist transistor 420 (e.g., a second pull-up device) is activated by pull-up enable signal 424 based on a voltage range of reference voltage supply 430 (e.g., a second reference supply voltage different from the first reference supply voltage) concurrently with the activation of pull-up transistor 413 (e g., the first pull-up device). Pull-up assist transistor 420 also passes the power supply voltage from reference voltage supply 316 to interconnect 130, which is electrically connected to driver circuit 124. In some embodiments, pull-up assist transistor 420 can be an n-type transistor.

Referring to FIG. 9, at operation 930, a current flows through a resistor device from a power supply source of the power supply voltage to the external circuit in response to the first pull-up device being activated and the second pull-up device being activated. Referring to

FIGS. 3 and 5-8, a current flows through resistor device 510, resistor device 610, resistor device 710, or resistor device 810 from reference voltage supply 316 (e.g., a power supply source of the power supply voltage) to interconnect 130—which is electrically connected to driver circuit 124—in response to pull-up transistor 413 (e.g., the first pull-up device) being activated and pull-up assist transistor 420 (e.g., the second pull-up device) being activated. In some embodiments, the current flows through resistor device 510 or resistor device 610, as well as pull-up transistor 413 and pull-up assist transistor 420, from reference voltage supply 316 to interconnect 130. In some embodiments, the current flows through resistor device 710 or resistor device 810, as well as pull-up assist transistor 420, from reference voltage supply 316 to interconnect 130. Resistor device 510, resistor device 610, resistor device 710, and resistor device 810 can mitigate variances in a resistance path between driver circuit 114 and driver circuit 124 and variances in a VOH of driver circuit 114, according to some embodiments.

Referring to FIG. 9, at operation 940, the power supply voltage is transferred from the driver circuit to an external circuit. Referring to FIG. 3, the power supply voltage associated with reference voltage supply 226 is transferred from driver circuit 114 (of chip 110) to driver circuit 124 (of chip 120; an external circuit). For example, this voltage transfer can occur during a memory write operation, as described above.

In summary, the disclosed embodiments are directed to a driver circuit for mitigating effects of power supply variations. Embodiments of the driver circuit can be used in a system, such as a memory system that includes DRAM cells. In some embodiments, the driver circuit can include a first transistor device with a first S/D terminal and a second S/D terminal. The driver circuit can also include a second transistor device with a third S/D terminal and a fourth S/D terminal. The driver circuit can further include a resistor device electrically connected between the first and third S/D terminals or between the second and fourth S/D terminals. Alternatively, the third S/D terminal can be electrically connected to the first S/D terminal, the fourth S/D terminal can be electrically connected to the second S/D terminal, and the resistor device can be electrically connected to the first and third S/D terminals or to the second and fourth S/D terminals. The resistor device can mitigate variations in a VOH of the driver circuit due to power supply variations (e.g., variations in reference voltage supply 430).

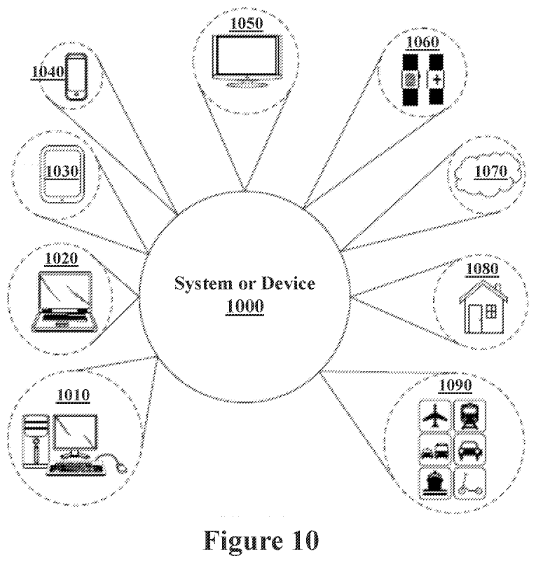

FIG. 10 is an illustration of exemplary systems or devices that can include the disclosed embodiments. System or device 1000 can incorporate one or more of the disclosed embodiments in a wide range of areas. For example, system or device 1000 can be implemented in one or more of a desktop computer 1010, a laptop computer 1020, a tablet computer 1030, a cellular or mobile phone 1040, and a television 1050 (or a set-top box in communication with a television).

Also, system or device 1000 can be implemented in a wearable device 1060, such as a smartwatch or a health-monitoring device. In some embodiments, the smartwatch can have different functions, such as access to email, cellular service, and calendar functions. Wearable device 1060 can also perform health-monitoring functions, such as monitoring a user's vital signs and performing epidemiological functions (e.g., contact tracing and providing communication to an emergency medical service). Wearable device 1060 can be worn on a user's neck, implantable in user's body, glasses or a helmet designed to provide computer-generated reality experiences (e.g., augmented and/or virtual reality), any other suitable wearable device, and combinations thereof.

Further, system or device 1000 can be implemented in a server computer system, such as a dedicated server or on shared hardware that implements a cloud-based service 1070. System or device 1000 can be implemented in other electronic devices, such as a home electronic device 1080 that includes a refrigerator, a thermostat, a security camera, and other suitable home electronic devices. The interconnection of such devices can be referred to as the “Internet of Things” (IoT). System or device 1000 can also be implemented in various modes of transportation 1090, such as part of a vehicle's control system, guidance system, and/or entertainment system.

The systems and devices illustrated in FIG. 10 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract section, is intended to be used to interpret the claims. The Abstract section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a first transistor device with a first source/drain (S/D) terminal and a second S/D terminal;
a second transistor device with a third S/D terminal and a fourth S/D terminal; and
a resistor device electrically connected between the first and third S/D terminals or between the second and fourth S/D terminals.

2. The circuit of claim 1, wherein the first transistor device comprises a p-type transistor and the second transistor comprises an n-type transistor.

3. The circuit of claim 1, wherein a first terminal of the resistor device is electrically connected to the first S/D terminal and to a reference voltage supply, a second terminal of the resistor device is electrically connected to the third S/D terminal, and the second and fourth S/D terminals are electrically connected to a driver circuit of a memory device.

4. The circuit of claim 1, wherein a first terminal of the resistor device is electrically connected to the second S/D terminal and to a driver circuit of a memory device, a second terminal of the resistor device is electrically connected to the fourth S/D terminal, and the first and third S/D terminals are electrically connected to a reference voltage supply.

5. The circuit of claim 1, wherein a ratio of an area of the resistor device to an area of each of the first and second transistor devices ranges from about 1.5 to about 2.0.

6. The circuit of claim 1, wherein a gate terminal of the first transistor device is electrically connected to a first reference voltage supply and a gate terminal of the second transistor device is electrically connected to a second reference voltage supply.

7. The circuit of claim 6, wherein the first reference voltage supply is electrically connected to the first and third S/D terminals.

8. The circuit of claim 6, wherein the first reference voltage supply is electrically connected to the first S/D terminal and to a terminal of the resistor device.

9. A circuit, comprising:
a first transistor device with a first source/drain (S/D) terminal and a second S/D terminal;
a second transistor device with a third S/D terminal and a fourth S/D terminal, wherein the third S/D terminal is electrically connected to the first S/D terminal and the fourth S/D terminal is electrically connected to the second S/D terminal; and
a resistor device electrically connected to the first and third S/D terminals or to the second and fourth S/D terminals.

10. The circuit of claim 9, wherein the first transistor device comprises a p-type transistor and the second transistor comprises an n-type transistor.

11. The circuit of claim 9, wherein a first terminal of the resistor device is electrically connected to the first and third S/D terminals, a second terminal of the resistor device is electrically connected to a reference voltage supply, and the second and fourth S/D terminals are electrically connected to a driver circuit of a memory device.

12. The circuit of claim 9, wherein a first terminal of the resistor device is electrically connected to the second and fourth S/D terminals, a second terminal of the resistor device is electrically connected to a driver circuit of a memory device, and the first and third S/D terminals are electrically connected to a reference voltage supply.

13. The circuit of claim 9, wherein a ratio of an area of the resistor device to an area of each of the first and second transistor devices ranges from about 1.5 to about 2.0.

14. The circuit of claim 9, wherein a gate terminal of the first transistor device is electrically connected to a first reference voltage supply and a gate terminal of the second transistor device is electrically connected to a second reference voltage supply.

15. The circuit of claim 14, wherein a first voltage range of the first reference voltage supply is different than a second voltage range of the second reference voltage supply.

16. The circuit of claim 15, wherein a minimum voltage of the first voltage range is lower than a minimum voltage of the second voltage range, and wherein a maximum voltage of the first voltage range is lower than a maximum voltage of the second voltage range.

17. A method, comprising:
activating, with a first reference supply voltage, a first pull-up device to pass a power supply voltage to an external circuit;
activating, with a second reference supply voltage different from the first reference supply voltage, a second pull-up device to pass the power supply voltage to the external circuit concurrently with the first pull-up device; and
in response to the first pull-up device being activated and the second pull-up device being activated, flowing a current through a resistor device from a power supply source of the power supply voltage to the external circuit.

18. The method of claim 17, wherein activating the first pull-up device comprises activating a p-type transistor configured to pass the power supply voltage to the external circuit.

19. The method of claim 17, wherein activating the second pull-up device comprises activating an n-type transistor configured to pass the power supply voltage to the external circuit.

20. The method of claim 19, wherein flowing the current through the resistor device comprises flowing the current through the resistor device and the n-type transistor from the power supply source to the external circuit.
